(19) United States
(12) Patent Application Publication
(10) Pub. No.: US 2018/0040513 A1
(43) Pub. Date: Feb. 8, 2018

(54) PROCESSING METHOD FOR WAFER

(71) Applicant: DISCO CORPORATION, Santa Clara, CA (US)

(72) Inventor: Chris Mihai, Santa Clara, CA (US)

(21) Appl. No.: 15/229,722

(22) Filed: Aug. 5, 2016

(51) Int. Cl. H01L 21/78; H01L 21/324; H01L 23/544; H01L 21/683

(52) U.S. Cl. CPC H01L 21/78; H01L 21/6836; H01L 21/3247; H01L 23/544; H01L 2221/68327; H01L 2223/54453

(57) ABSTRACT

A wafer processing method of dividing along a plurality of projected dicing lines set on the wafer includes a placing step of placing the wafer on a heating table with a tape interposed therebetween, the wafer having modified layers, from which to start to divide the wafer, formed therein at positions aligned with the projected dicing lines, the tape being applied to one surface of the wafer, and a dividing step of dividing the wafer on the heating table by heating with the heating table and thereafter cooling an exposed opposite surface in its entirety of the wafer with a cooing unit whereby the wafer starts being ruptured from the modified layers along the projected dicing lines due to a thermal shock caused by a temperature difference developed between the heated and cooled surfaces of the wafer.

### BACKGROUND OF THE INVENTION

### Field of the Invention

The present invention relates to a wafer processing method, applicable to the division of a wafer along projected dicing lines thereon.

### Description of the Related Art

Electronic devices that are typified by mobile phones and personal computers include as indispensable components device chips that are provided with devices such as electronic circuits, etc. Device chips are manufactured by demarcating the surface of a wafer made of a semiconductor material such as silicon, gallium arsenide, or the like, for example, with projected dicing lines also known as streets, forming devices in the demarcated areas, and dividing the wafer along the projected dicing lines.

According to one known process (SD: Stealth Dicing) for dividing such a wafer, a transmittable laser beam is focused inside the wafer to form a modified layer (modified region) therein by way of multiphoton absorption (see, for example, Japanese Patent Laid-open No. 2002-192370). After modified layers have been formed along respective projected dicing lines on the wafer, a mechanical stress is applied to the wafer by a blade-shaped member or the like, for example, starting to divide the wafer from the modified layers into a plurality of device chips (see, for example, Japanese Patent Laid-open No. 2016-40810).

### SUMMARY OF THE INVENTION

However, since the wafer referred to above is generally brittle, the process that applies a mechanical stress to the wafer is likely to chip off the edges of the device chips. Furthermore, inasmuch as it is necessary to apply the mechanical stress to the wafer all along the projected dicing lines, if the device chips are reduced in size, e.g., to a size of 1 mm in length×1 mm in width, then the time required to divide the wafer is increased.

It is therefore an object of the present invention to provide a wafer processing method in order to divide the wafer within a short period of time while preventing the wafer from being chipped off.

According to an aspect of the present invention, there is provided a wafer processing method of dividing along a plurality of projected dicing lines set on the wafer, including: a placing step of placing the wafer on a heating table with a tape interposed therebetween, the wafer having modified layers, from which to start to divide the wafer, formed therein at positions aligned with the projected dicing lines, the tape being applied to one surface of the wafer, and a dividing step of dividing the wafer on the heating table by heating with the heating table and thereafter cooling an exposed opposite surface in its entirety of the wafer with a cooing unit whereby the wafer starts being ruptured from the modified layers along the projected dicing lines due to a thermal shock caused by a temperature difference developed between the heated and cooled surfaces of the wafer.

According an aspect of the present invention, the cooling unit may eject a cooling fluid to the exposed opposite surface in its entirety of the wafer. Alternatively, the cooling unit may have a contact surface for contacting the exposed opposite surface in its entirety of the wafer, and cools the contact surface by the Peltier effect.

Since the wafer processing method according to the first-mentioned aspect of the present invention divides the wafer utilizing the thermal shock caused by the temperature difference developed between the heated and cooled surfaces of the wafer, it is not necessary to apply a mechanical force to the wafer to divide the same. Consequently, the wafer is prevented from being chipped off due to a mechanical force which would otherwise be applied. Furthermore, as the thermal shock acts on the wafer in its entirety the wafer can be divided along all the projected dicing lines in a short period of time.

The above and other objects, features and advantages of the present invention and the manner of realizing them will become more apparent, and the invention itself will best be understood from a study of the following description and appended claims with reference to the attaching drawings showing preferred embodiments of the invention.

### BRIEF DESCRIPTION OF THE DRAWINGS

FIG. 1A is a perspective view schematically showing a structural example of a wafer;

FIG. 1B is a perspective view schematically showing the wafer which is supported on an annular frame;

FIG. 2A is a side elevational view, partly in cross section, schematically showing a modified layers forming step;

FIG. 2B is a side elevational view, partly in cross section, schematically showing a placing step and a dividing step;

FIG. 2C is a side elevational view, partly in cross section, schematically showing a wafer that has been ruptured;

FIG. 3A is a side elevational view, partly in cross section, schematically showing a dividing step according to a modification; and

FIG. 3B is a side elevational view, partly in cross section, schematically showing a wafer that has been ruptured according to the modification.

### DETAILED DESCRIPTION OF THE PREFERRED EMBODIMENTS

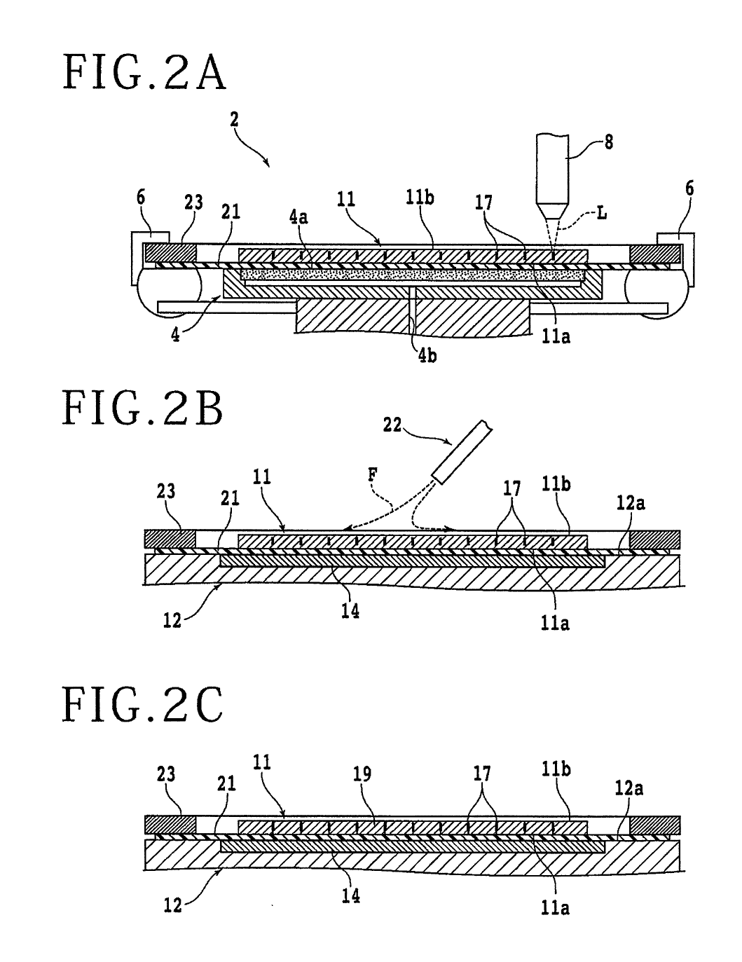

Preferred embodiments of the present invention will be described below with reference to the accompanying drawings. A wafer processing method according to an embodiment of present invention includes a placing step (see FIG. 2B) and a dividing step (see FIGS. 2B and 2C), which will briefly be described below. In the placing step, a wafer having therein modified layers from which to start dividing the wafer is placed on a heating table for heating the wafer. In the dividing step, the heating table heats the wafer from its surface that is held in contact with the heating table, and then the other exposed surface of the wafer is cooled in its entirety thereby rupturing the wafer due to a thermal shock caused by the temperature difference between the heated and cooled surfaces. The wafer processing method according to the present embodiment will be described in detail below.

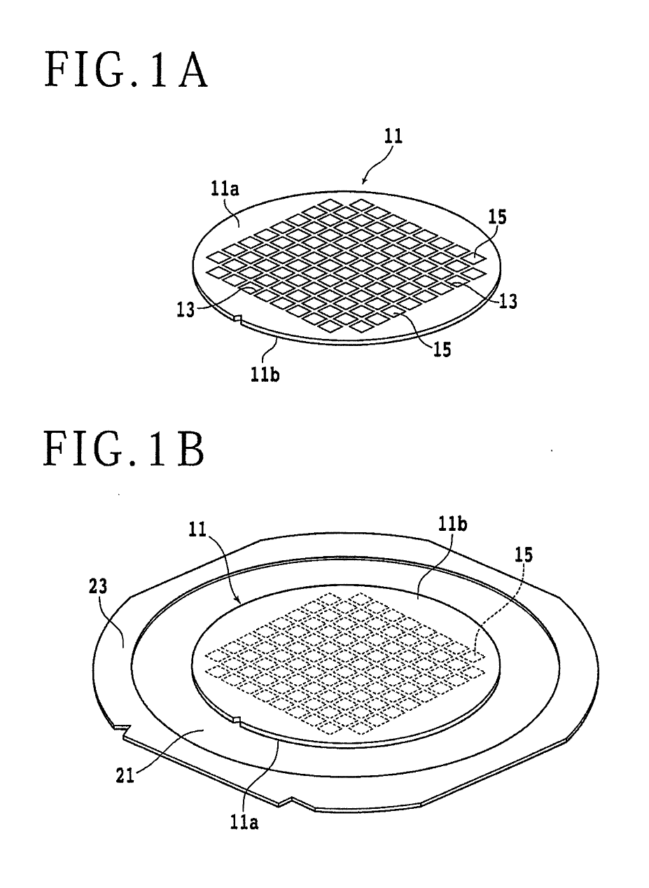

FIG. 1A is a perspective view schematically showing a structural example of a wafer 11. As shown in FIG. 1A, the wafer 11 is in the shape of a disk made of a semiconductor material such as silicon (Si), gallium arsenide (GaAs), or the like. The wafer 11 has a front surface 11a separated into a central device region and an outer peripheral extra region surrounding the central device region. The central device region is demarcated into a plurality areas by a plurality of projected dicing lines 13, also known as streets, arranged in a grid pattern, with a device 15 such as an integrated circuit (IC), a large-scale integration (LSI), or the like formed in each of the demarcated areas. The wafer 11 is not limited to any particular material, shape, and structure. A substrate made of ceramics, resin, or metal, for example, may be used as the wafer 11.

FIG. 1B is a perspective view schematically showing the wafer 11 which is supported on an annular frame 23. As shown in FIG. 1B, a tape 21 that is larger in diameter than the wafer 11 is applied to the front surface 11a of the wafer 11. The tape 21 has an outer peripheral portion to which the annular frame 23 is secured. The wafer 11 is thus supported by the frame 23 through the tape 21.

After the wafer 11 has been supported by the frame 23, modified layers from which to start to divide the wafer 11 are formed within the wafer 11. FIG. 2A is a side elevational view, partly in cross section, schematically showing a modified layers forming step of forming modified layers within the wafer 11. The modified layers forming step is carried out using a laser processing apparatus 2 shown in FIG. 2A, for example.

The laser processing apparatus 2 is provided with a disk-shaped holding table 4 for attracting under suction and holding the wafer 11. The holding table 4 is coupled to a rotary actuator (not shown) such as a motor or the like, and is rotatable about a rotational axis extending substantially parallel to vertical directions. The holding table 4 is horizontally movable by a moving mechanism (not shown) disposed below the holding table 4. The holding table 4 has an upper surface serving as a holding surface 4a for attracting under suction and holding the front surface 11a of the wafer 11 through the tape 21. The holding surface 4a is connected to a suction source (not shown) through a channel 4b defined in the holding table 4. A plurality of clamps 6 for securing a frame 23 that supports the wafer 11 are disposed around the holding table 4. The laser processing apparatus 2 includes a laser processing unit 8 disposed above the holding table 4. The laser processing unit 8 focuses a laser beam L that has been pulse-oscillated by a laser oscillator (not shown) inside the wafer 11 that is attracted under suction and held on the holder table 4. The laser oscillator is arranged to oscillate the laser beam L at a wavelength that transmits the wafer 11, i.e., a wavelength that is hard to be absorbed by the wafer 11.

In the modified layers forming step, the wafer 11 is placed on the holding table 4 with the tape 21 interposed therebetween so that the tape 21 applied to the front surface 11a of the wafer 11 and the holding surface 4a of the holding table 4 face each other. The frame 23 is secured in position by the clamps 6. Then, a negative pressure produced by the suction source is applied through the channel 4b to the holding surface 4a to attract under suction and hold the wafer 11 on the holding table 4 with the wafer 11 having a back surface 11b exposed upwardly. Then, the holding table 4 is moved and rotated to position the laser processing unit 8 above one of the projected dicing lines 13 to be processed in alignment therewith. Thereafter, the laser processing unit 8 applies the laser beam L to the wafer 11 while at the same time the holding table 4 is moved in a direction parallel to the projected dicing line 13 to be processed. The applied laser beam L causes multiphoton absorption in the vicinity of a focal point where the laser beam L is focused inside the wafer 11, thereby forming modified layers 17 within the wafer 11 along the projected dicing line 13 to be processed. Various conditions including the wavelength, power density, and repetition frequency of the laser beam L, and the speed at which the holding table 4 moves are set in ranges for forming the modified layers 17 suitable for the division of the wafer 11. The above processing sequence is repeated to form modified layers 17 along all the projected dicing lines 13, i.e., at positions aligned with all the projected dicing lines 13, whereupon the modified layers forming step is ended.

After the modified layers forming step, the wafer 11 is divided by the wafer processing method according to the present embodiment. Specifically, the placing step is carried out to place the wafer 11 including the modified layers 17 from which to start to divide the wafer 11, on a heating table. FIG. 2B is a side elevational view, partly in cross section, schematically showing the placing step and the dividing step.

In the placing step, as shown in FIG. 2B, the wafer 11 is placed on an upper surface 12a of a heating table 12, which is of a disk shape greater in diameter than the wafer 11, with the tape 21 interposed between the wafer 11 and the upper surface 12a. As a result, the back surface 11b of the wafer 11 is exposed upwardly. A heater 14 for heating the wafer 11 is disposed in the upper surface 12a of the heating table 12. The heater 14 is capable of heating the entire front surface 11a of the wafer 11.

The placing step is followed by the dividing step wherein the wafer 11 is ruptured by a thermal shock. In the dividing step, the entire front surface 11a of the wafer 11 is heated to a predetermined temperature by the heater 14 described above. Conditions for heating the entire front surface 11a of the wafer 11 are arbitrary. According to the present embodiment, however, the temperature of the heater 14 is set to 95° C., and the front surface 11a of the wafer 11 is heated to 85° C. or higher by the heater 14. When the front surface 11a of the wafer 11 is heated to 85° C. or higher, it is easy to establish a temperature difference across the wafer 11 that is necessary to cause a thermal shock. According to the present embodiment, the heater 14 is energized after the placing step has been completed. However, the heater 14 may be energized before the placing step is completed, i.e., before the placing step is carried out or while the placing step is being carried. In this case, since the wafer 14 starts being heated immediately after it has been placed on the heating table 12 in the placing step, the time required to divide the wafer 11 is reduced for an increased throughput.

After the wafer 11 has been heated, the entire exposed back surface 11b of the wafer 11 is quickly cooled to develop a large temperature difference across the wafer 11, i.e., between the front surface 11a and the back surface 11b of the wafer 11. According to the present embodiment, as shown in FIG. 2B, the temperature difference is developed by applying a cooling fluid F to the entire back surface 11b of the wafer 11. Specifically, an ejection nozzle (cooling unit) 22 is disposed above the heating table 12, and a cooling fluid F is ejected from the ejection nozzle 22 to the back surface 11b of the wafer 11. The cooling fluid F may be a gas such as air or the like that has been sufficiently cooled or a liquid such as water, a solution, or the like. If a liquid is used as the fluid F, then the liquid may be cooled to a temperature not low enough to freeze the liquid, e.g., a temperature higher than its freezing point by a temperature in the range from 0.1° C. to 10° C. Alternatively, a low-temperature volatile liquid that is capable of removing heat from the wafer 11 upon its vaporization may be used as the fluid F. In this case, the low-temperature volatile liquid allows the necessary temperature difference to be developed easily as it can quickly cool the back surface 11b of the wafer 11. The necessary temperature difference refers to a temperature difference for bringing out a thermal shock in excess of the rupture stress of the wafer 11. The temperature difference is determined depending on the material and thickness of the wafer 11 and the state of the modified layers 17 in the wafer 11, for example. Conditions such as the type and flow rate of the fluid F are set in ranges for developing the necessary temperature difference.

When the cooling liquid F is applied to the entire back surface 11b of the wafer 11, developing a sufficient temperature difference across the wafer 11, the wafer 11 starts being ruptured from the modified layers 17 due to a thermal shock. FIG. 2C is a side elevational view, partly in cross section, schematically showing the wafer 11 that has been ruptured. When the wafer 11 is divided into a plurality of device chips 19 along the projected dicing lines 13, the dividing step is finished.

In the wafer processing method according to the present embodiment, as described above, as much as the wafer 11 is divided utilizing a thermal shock caused by the temperature difference between the heated and cooled surfaces of the wafer 11, it is not necessary to apply a mechanical force to the wafer 11 to divide the same. Consequently, the wafer 11 is prevented from being chipped off due to a mechanical force which would otherwise be applied. Furthermore, as the thermal shock acts on the wafer 11 in its entirety the wafer 11 can be divided along all the projected dicing lines 13 in a short period of time.

The present invention is not limited to the above illustrated embodiment, but many changes and modifications may be made therein. In the illustrated embodiment, the tape 21 is applied to the front surface 11a of the wafer 11 and the back surface 11b of the water 11 is exposed. However, the tape 21 may be applied to the back surface 11b of the wafer 11 and the front surface 11a of the water 11 may be exposed. In other words, the back surface 11b of the wafer 11 may be heated and the front surface 11a of the water 11 may be cooled.

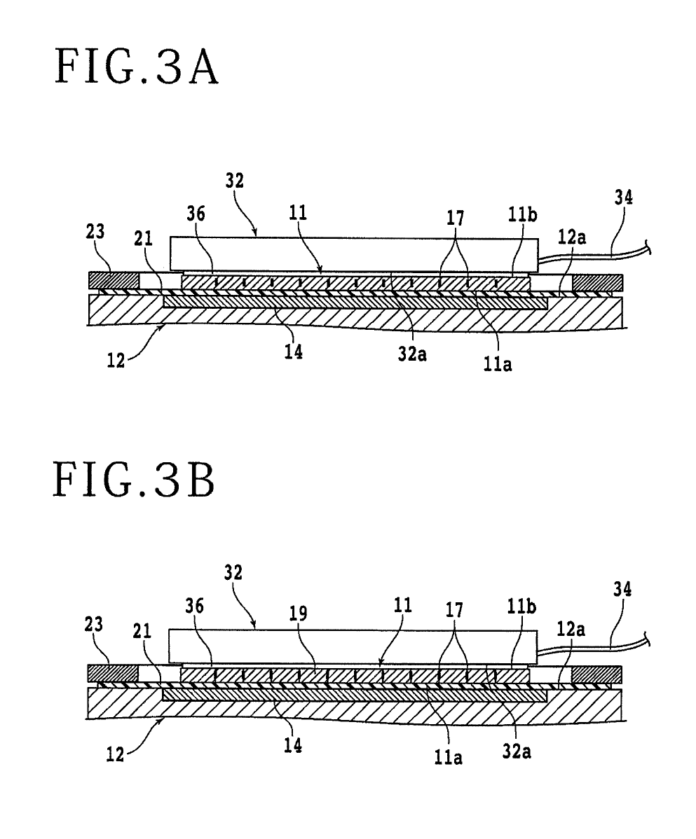

In the wafer processing method according to the present embodiment, moreover, the temperature difference is developed across the wafer 11 by applying the cooling fluid F to the entire back surface 11b of the wafer 11. However, the present invention is not limited to any process of developing a temperature difference across the wafer 11. FIG. 3A is a side elevational view, partly in cross section, schematically showing a dividing step according to a modification, and FIG. 3B is a side elevational view, partly in cross section, schematically showing a wafer that has been ruptured according to the modification.

In the dividing step according to the modification, a temperature difference is developed across a wafer 11 using a Peltier device (cooling unit) 32. The Peltier device 32 is made of two different metals joined to each other, for example, and has a cooling surface (contact surface) 32a which is cooled when the Peltier device 32 is supplied with electric power (voltage). The cooling surface 32a is of a size large enough to contact the entire back surface 11b of the wafer 11. Electric wires 34 for supplying electric power (voltage) are connected to the Peltier device 32.

In the dividing step according to the modification, the entire front surface 11a of the wafer 11 is heated in the same manner as with the dividing step according to the embodiment shown in FIG. 2B. After the wafer 11 has been heated, the cooling surface 32a of the Peltier device 32 described above is brought into contact with the back surface 11b of the wafer 11 with a gel 36 of high thermal conductivity interposed therebetween. However, the gel 36 may be dispensed with. Thereafter, electric power (voltage) is supplied through the electric wires 34 to the Peltier device 32, cooling the cooling surface 32a of the Peltier device 32. The entire back surface 11b of the wafer 11 is now quickly cooled, developing a large temperature difference across the wafer 11, i.e., between the front surface 11a and the back surface 11b of the wafer 11. When the sufficient temperature difference is developed across the wafer 11, the wafer 11 starts being ruptured from the modified layers 17 due to a thermal shock. When the wafer 11 is divided into a plurality of device chips 19 along the projected dicing lines 13, the dividing step is finished.

According to the modification, the cooling surface 32a of the Peltier device 32 is brought into contact with the back surface 11b of the wafer 11 after the front surface 11a thereof has been heated. However, the cooling surface 32a of the Peltier device 32 may be brought into contact with the back surface 11b of the wafer 11 before the front surface 11a thereof is heated. Alternatively, the cooling surface 32a of the Peltier device 32 that has already been cooled may be brought into contact with the back surface 11b of the wafer 11 after the front surface 11a thereof has been heated. According to the latter alternative, as the back surface 11b of the wafer 11 is cooled more quickly, it is easy to develop the necessary temperature difference across the wafer 11.

The present invention is not limited to the details of the above described preferred embodiments. The scope of the invention is defined by the appended claims and all changes and modifications as fall within the equivalence of the scope of the claims are therefore to be embraced by the invention.

1. A wafer processing method of dividing along a plurality of projected dicing lines set on the wafer, comprising:
a placing step of placing the wafer on a heating table with a tape interposed therebetween, wherein said tape is in contact with said heating table, said wafer having modified layers, from which to start to divide the wafer, formed therein at positions aligned with the projected dicing lines, said tape being applied to one surface of said wafer; and
a dividing step of dividing said wafer on the heating table by heating with the heating table and thereafter cooling an exposed opposite surface in its entirety of the wafer with a cooing unit whereby said wafer starts being ruptured from the modified layers along the projected dicing lines due to a thermal shock caused by a temperature difference developed between the heated and cooled surfaces of the wafer.

2. The wafer processing method according to claim 1, wherein said cooling unit ejects a cooling fluid to the exposed opposite surface in its entirety of the wafer.

3. The wafer processing method according to claim 1, wherein said cooling unit has a contact surface for contacting the exposed opposite surface in its entirety of the wafer, and cools the contact surface by the Peltier effect.

4. The wafer processing method according to claim 1, wherein:
the tape is larger in diameter than the wafer;
the tape has an outer peripheral portion to which an annular frame is secured; and
the wafer is supported by the frame through the tape.

5. The wafer processing method according to claim 1, wherein the wafer is formed of a semiconductor material.

6. The wafer processing method according to claim 5, wherein the semiconductor material is silicon or gallium arsenide.

7. The wafer processing method according to claim 1, wherein the wafer is formed of a material chosen from the following materials: a ceramic and a metal.

8. The wafer processing method according to claim 1, further comprising:
a supporting step of positioning the wafer on the tape with an annular frame secured on an outer peripheral portion thereof, such that the wafer is supported by the frame through the tape.

9. A wafer processing method of dividing along a plurality of projected dicing lines set on the wafer, comprising:
a supporting step of positioning the wafer on a tape with an annular frame secured on an outer peripheral portion thereof, such that the wafer is supported by the frame through the tape.
a placing step of placing the wafer on a heating table with the tape interposed therebetween, wherein said tape is in contact with both said heating table and said wafer, said wafer having modified layers, from which to start to divide the wafer, formed therein at positions aligned with the projected dicing lines, said tape being applied to one surface of said wafer; and
a dividing step of dividing said wafer on the heating table by heating with the heating table and thereafter cooling an exposed opposite surface in its entirety of the wafer with a cooing unit whereby said wafer starts being ruptured from the modified layers along the projected dicing lines due to a thermal shock caused by a temperature difference developed between the heated and cooled surfaces of the wafer.

10. The wafer processing method according to claim 9, wherein said cooling unit ejects a cooling fluid to the exposed opposite surface in its entirety of the wafer.

11. The wafer processing method according to claim 9, wherein said cooling unit has a contact surface for contacting the exposed opposite surface in its entirety of the wafer, and cools the contact surface by the Peltier effect.

12. The wafer processing method according to claim 9, wherein:
the tape is larger in diameter than the wafer;
the tape has an outer peripheral portion to which an annular frame is secured; and
the wafer is supported by the frame through the tape.

13. The wafer processing method according to claim 9, wherein the wafer is formed of a semiconductor material.

14. The wafer processing method according to claim 13, wherein the semiconductor material is silicon or gallium arsenide.

15. The wafer processing method according to claim 9, wherein the wafer is formed of a material chosen from the following materials: a ceramic and a metal.
